(19) United States
(12) Patent Application Publication
(10) Pub. No.: US 2005/0117313 A1
(43) Pub. Date: Jun. 2, 2005

(54) Electric card fixture

(75) Inventor: Chun-Sheng Wang, Gueishan Township (TW)

Correspondence Address: TROXELL LAW OFFICE PLLC, SUITE 1404, 5205 LEESBURG PIKE, FALLS CHURCH, VA, 22041, US

(73) Assignee: Speed Tech Corp.

(21) Appl. No.: 10/722,604

(22) Filed: Nov. 28, 2003

(51) Int. Cl. H05K 7/12

(52) U.S. Cl. 361/753; 361/759

(57) ABSTRACT

The present invention provides an electric card fixture for fastening the electric card. The electric card fixture comprises a base having an opening and a pivot member, pivotally connecting to one end of the base. By the base on the circuit board, the electric card is restricted by the opening of the base to a predetermined position. Therefore, the electric card is positioned. The pivot member presses the electric card, so that the electric card will not flip upward. Accordingly, the electric card fixture locks up the electric card, so that the electric card will not fall off when shaken and therefore provides prefect electrical connection.

### FIELD OF THE INVENTION

The present invention is related to an electric card fixture. More particularly, the electric card is restricted by the electric card fixture to a predetermined position, so that the electric card will not flip upward. Accordingly, the electric card fixture locks up the electric card, so that the electric card will not fall off when shaken and therefore provides prefect electrical connection.

### BACKGROUND OF THE INVENTION

In the prior art, the electric card fastener, disclosed in the Taiwan Patent No. 545747, configured to a circuit board, includes: a connector, configured on the circuit board, having a non-conduct body and a slot disposed in front of the non-conduct body, wherein a plurality of terminals are disposed in the slot; an electric card with its front end inserted in the slot, wherein a lock portion is disposed on the electric card; and at least one hook member, made of plastic material in one-piece shape with hooks extending upward, configured on the circuit board apart from the connector, wherein the hook portion hooks the lock portion for fastening the electric card.

The conventional electric card fastener can fasten the lock portion of the electric card by the hooks of the hook members so as to fasten the electric card. However, the electric card is restricted in the hook member by compulsion. After multiple uses (attachment and detachment), since they are made of different materials, the electric card and the hook member may wear each other and crack down. Therefore, when being shaken, the electric card might shift away and flip upward. The electric card can not move in X, Y and Z directions and is easy to fall off, so that the electrical connection of the electric card is poor. In addition, since the conventional electric card fastener is made of plastic material, the hook member can not be used for ground connection if there is any grounding circuit on the circuit board. Accordingly, the conventional fastener can hardly meet users' needs.

### SUMMARY OF THE INVENTION

The main objective of the present invention is that by the restriction of the electric card fixture, the electric card will not shift away or flip upward. Accordingly, the electric card fixture restricts the electric card in a predetermined position, so that the electric card will not fall off when shaken and therefore provides prefect electrical connection.

Another objective of the present invention is that a pivot member presses the electric card to mount it. Further compare to the prior art, the present invention could prevent abrasion and facilitate replacement.

To achieve the above objective, the present invention provides an electric card fixture, which has a base having an opening and a joint portion disposed in one end of the base, and a pivot member, pivotally connecting to the other end of the base. By the base on the circuit board, the electric card is restricted by the opening of the base to a predetermined position. Therefore, the electric card will not shift away. The pivot member presses the electric card, so that the electric card will not flip upward. Accordingly, the electric card fixture restricts the electric card in a predetermined position, so that the electric card will not fall off when shaken and therefore provides prefect electrical connection.

### BRIEF DESCRIPTION OF THE DRAWINGS

The present invention will be better understood from the following detailed description of preferred embodiments of the invention, taken in conjunction with the accompanying drawings, in which

FIG. 1 is a diagram showing an outward appearance according to the present invention;

FIG. 2 is a diagram showing an outward appearance according to the present invention in another view angle;

FIG. 3 illustrates how the electric card fixture is like in use according to the present invention; and

FIG. 4-1 and FIG. 4-2 are diagrams showing an operation configuration of the present invention.

### DETAIL DESCRIPTION OF THE INVENTION

The following descriptions of the preferred embodiments are provided to understand the features and the structures of the present invention.

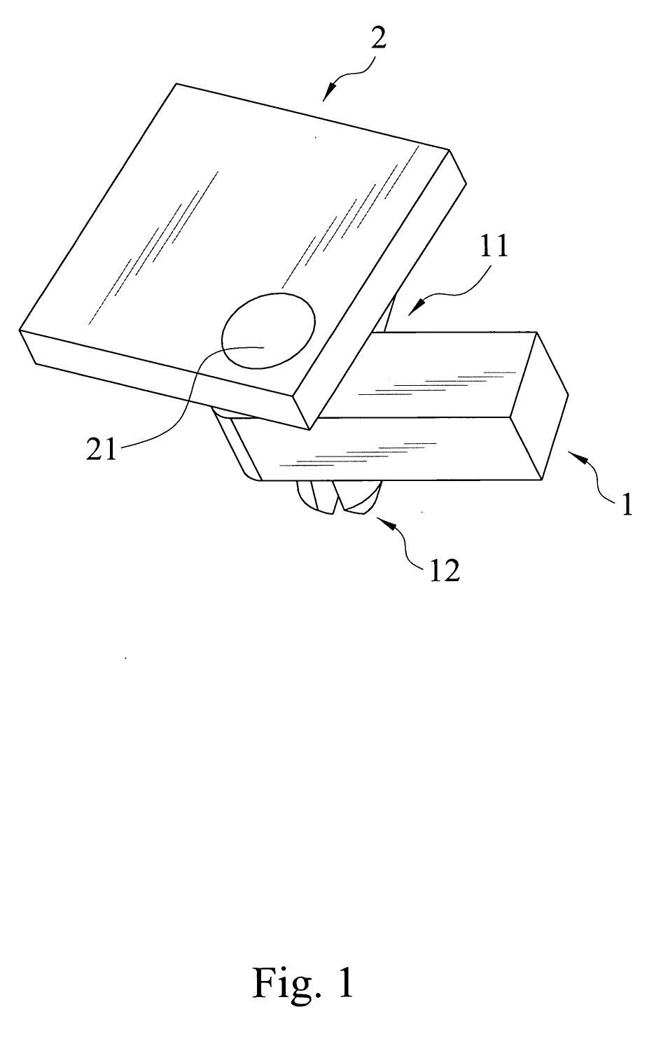

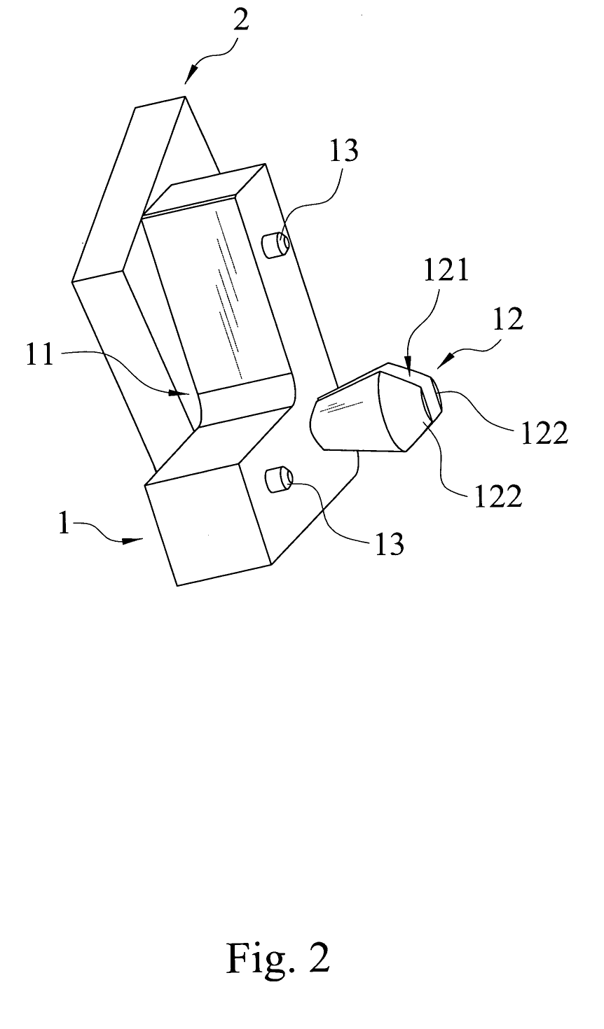

FIG. 1 and FIG. 2 are respectively a diagram showing an outward appearance of the present invention and a diagram showing an outward appearance of the present invention in another view angle. As shown in the diagram, the present invention provides an electric card fixture, configured to a circuit board, for fastening the electric card. The electric card fixture comprises a base 1 and a pivot member 2. By the restriction from the base 1 of the fixture and the pivot member 2, the electric card will not shift away and will not flip upward. The electric card fixture restricts the electric card in a predetermined position, so that the electric card will not fall off when shaken and therefore provides prefect electrical connection. Since the base 1 and the pivot member 2 are made of metal material, a joint portion 12 of the electric card fixture can be used to connect ground.

The base 1 mentioned above has an opening 11. A joint portion 12 is disposed in one end of the base 1. The joint portion 12 of the base 1 can mount the base 1 on the circuit board by surface mounting technology. The joint portion 12 is a lock member with a slot 121. By the slot 121, the joint portion 12 becomes two lock pieces 122. Also, at least one mounted portion 13 is disposed nearby the joint portion 12 and makes the joint portion 12 work as a board lock. Accordingly, the joint portion 12 can stick and mount the base 1 on the circuit board to meet realistic needs.

The pivot member 2 has a rectangular figure. With an axis 21, the pivot member 2 pivotally connects to another end of the base 1. When the pivot member 2 pivots to a certain point, it can be locked above the opening 11 of the base 1. Therefore, a novel electric card fixture is provided.

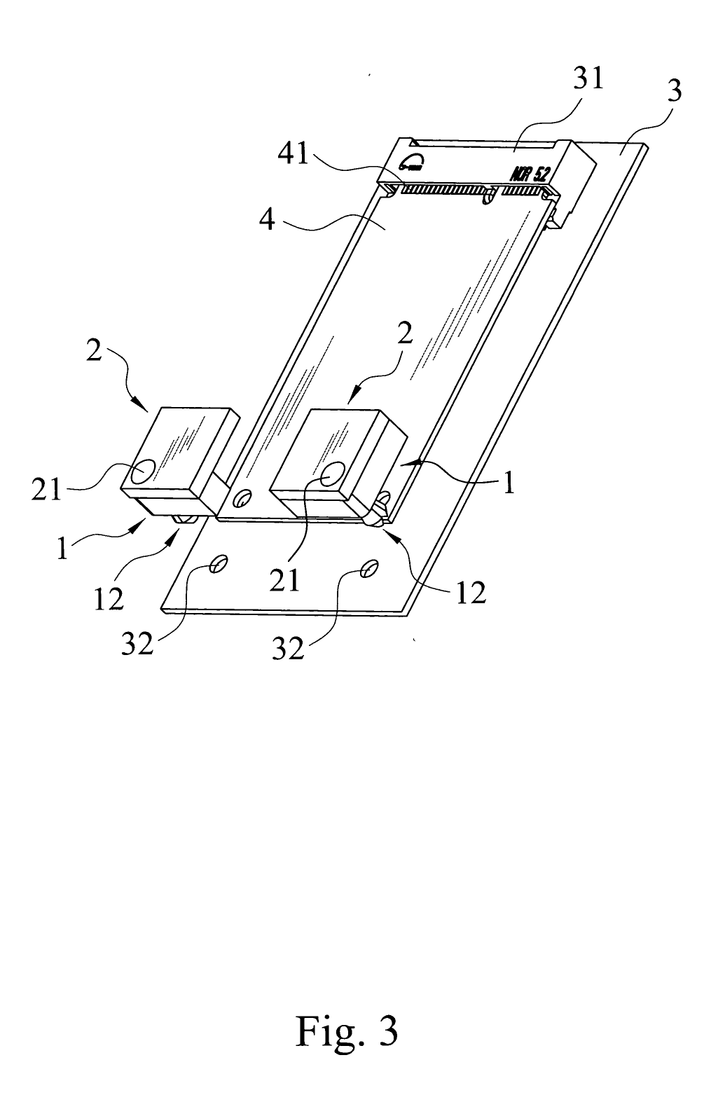

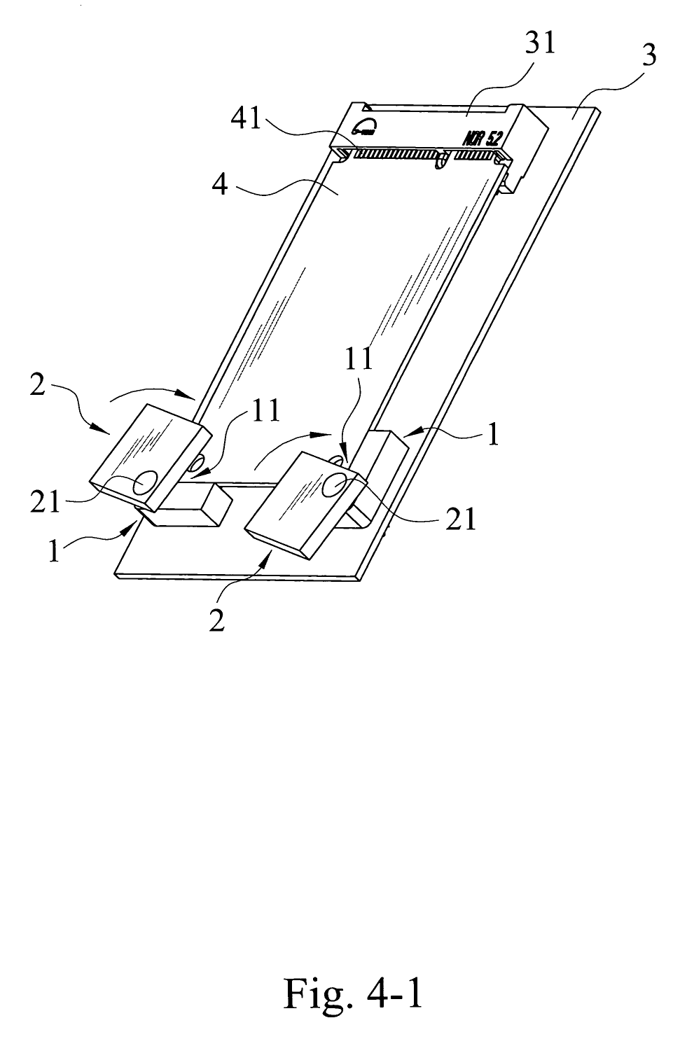

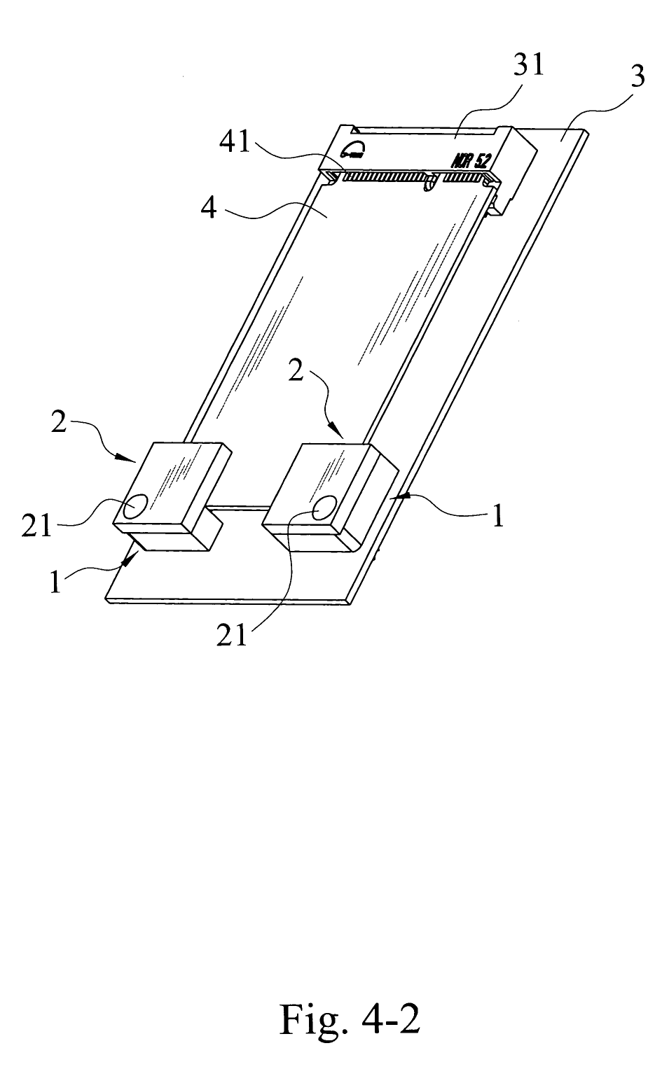

FIG. 3 and FIG. 4-1, 4-2 are diagrams showing a fabrication configuration of the present invention and a diagram showing an operation configuration of the present invention. As shown in the drawings, when using, two electric card fixtures of the present invention can be mounted in a circuit board 3. The distance between two electric card fixtures depend on the distance of the connector 31 on the circuit board and the size of the electric card 4. The openings 11 of those two bases 1 are correspondingly disposed. When being mounted, the joint portion 12 in one end of the base 1 is disposed correspondingly to the preset hole 32 on the circuit board 3. When the joint portion 12 of the base 1 is mounted in the hole 32 on the circuit board 3, by the slot 121, the joint portion 12 first forces the two pieces 122 of the joint portion 12 to be compressed inward, and after the joint portion 12 passes through the hole 32 on the circuit board 3, makes the two pieces 122 enlarge outward to recover its elasticity. Therefore, the joint portion 12 is mounted in the hole 32 on the circuit board 3. Meanwhile, the mounted portion 13 disposed nearby the joint portion 12 is also disposed correspondingly to a preset hole (not shown) on the circuit board 3. The mounted portion 13 restricts the base 1 from right or left side of movement. Accordingly, the fabrication is completed.

When users insert the electric card 4, the contact terminal part 41 of the electric card 4 is inserted to the connector 31 on a slant. The electric card 4 is then pushed down toward the circuit board 3 so that the other end of the electric card 4, without contact terminal part, is disposed in the opening 11 in one side of the base 1. After that, the pivot member is turned and by the axis 21, the pivot member 2 will rotate pivotally in another side of the base 1. The pivot member 2 seals the opening 11 of the base 1 when being turned to a certain position. Therefore, one end of the electric card 4 is restricted by the opening 11 of the base 1, so that the electric card 4 will not do parallel shift. The pivot member 2 presses the electric card 4 to prevent the electric card from flipping upward, so as to mount the electric card 4. Accordingly, by the fixture, the electric card 4 is limited by movement in X, Y and Z directions and is hard to fall off when shaken, so that the electrical connection of the electric card is prefect.

The description mention above is only a preferred embodiment of the present invention, which is not a limitation to the scope of the claimed invention. Therefore, any modification and variation in according with the claims and the specification of the present invention shall be covered within the scope of the present invention.

1. An electric card fixture, configured to a circuit board for fastening said electric card, said electric card fixture comprising:
a base, said base has an opening and a joint portion disposed in one end of said base for being mounted on said circuit board;
a pivot member, pivotally connecting to the other end of said base, wherein said pivot member seals said opening of said base when being turned to a certain position.

2. The electric card fixture according to claim 1, wherein said base and said pivot member are made of metal, so that said electric card fixture can be connected to ground by means of said joint portion.

3. The electric card fixture according to claim 1, wherein said joint portion of said base is a lock member with a slot, by said slot, said lock member becomes two lock pieces and makes said joint portion work as a board lock.

4. The electric card fixture according to claim 1, wherein at least one mounted portion is disposed on a proper position nearby said joint portion.

5. The electric card fixture according to claim 1, wherein said joint portion of said base mounts said base on said circuit board by surface mounting technology.
